(19) United States
(12) Patent Application Publication
(10) Pub. No.: US 2008/0217604 A1
(43) Pub. Date: Sep. 11, 2008

(54) Organic Semiconductor Film, Electron Device Using the Same and Manufacturing Method Therefor

(75) Inventors: Masaaki Yokoyama, Hyogo (JP); Takanori Nakano, Osaka (JP); Kazuo Nishimura, Osaka (JP); Masaichirou Tatekawa, Osaka (JP); Atsushi Sogami, Hyogo (JP); Tetsurou Nakamura, Hyogo (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., OSAKA (JP)

(21) Appl. No.: 10/568,934

(22) PCT Filed: Aug. 25, 2004
(86) PCT No.: PCT/JP04/12581

§ 371 Date: Feb. 21, 2006

(30) Foreign Application Priority Data
Aug. 29, 2003 (JP) 2003-307247

(51) Int. Cl. H01L 51/00; H01L 51/40

(52) U.S. Cl. 257/40; 438/99; 257/E51.001

(57) ABSTRACT

An organic semiconductor film that can be used for an electron device, for example, particularly can be used for organic TFTs so as to allow the TFTs to have advanced performance, is provided and a manufacturing method therefor is provided. For instance, the organic semiconductor film contains the organic conductive high polymer compound such as polythiophene represented by the below formula (I). The organic semiconductor film is formed by forming a solution in a thin film form, the solution showing two or more spectral peaks (spectral state B) in a wavelength region of 300 to 800 nm by measurement using a visible and ultraviolet absorption spectral method; and drying the solution formed in the thin film form. Alternatively, the organic semiconductor film can be formed by the method in which the organic conductive high polymer compound has a molecular weight distribution range Mw/Mn from 1.00 to 1.85, obtained by dividing a weight-average molecular weight Mw by a number-average molecular weight Mn. With these methods, principal chains of the organic conductive high polymer compound molecules are arranged substantially in parallel, thus enhancing carrier mobility.

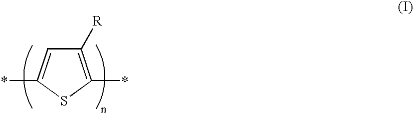

### TECHNICAL FIELD

The present invention relates to an organic semiconductor film, an electron device using the same and a manufacturing method therefor.

### BACKGROUND ART

In recent years, various electron devices employing an organic material for forming a semiconductor layer (semiconductor film), especially such thin film transistors (TFTs), have been proposed, and research and development thereof has been conducted vigorously. There are many advantages in employing an organic material as a semiconductor layer. For instance, while conventional inorganic thin film transistors based on inorganic amorphous silicon, etc., require a heating process at about 350 to 400° C., organic TFTs can be manufactured by a low-temperature heating process at about 50 to 200° C. As another advantage of the organic materials, a semiconductor layer can be formed by a simple process like a spin coating method, an ink jet method, printing or the like. Thus a large-area device can be manufactured at a low cost.

As one index used for determining the performance of a TFT, carrier mobility of a semiconductor layer thereof is available, and numerous studies have been conducted for improving the carrier mobility of an organic semiconductor layer (organic semiconductor film) in an organic TFT. Among these studies, a study focusing on molecules of an organic material making up an organic semiconductor layer (organic semiconductor film) includes one employing poly (3-alkylthiophene), for example (see JP H10(1998)-190001, for example). Further, as a study focusing on the structure of an organic TFT, there is proposed a study of making an alignment layer intervening between a gate insulation layer and an organic semiconductor layer for improving the crystal alignment property of the organic semiconductor layer, thus leading to the improvement of the carrier mobility (see JP H09(1997)-232589 A, for example). In this way, obtaining an organic semiconductor film having favorable properties leads to the improvement of the performance of an electron device. Thus, further study is required for enhancing the properties of an inorganic semiconductor film and an electron device.

### DISCLOSURE OF INVENTION

Therefore, it is an object of the present invention to provide an organic semiconductor film that can be used for an electron device or the like, particularly can be used for organic TFTs so as to allow the TFTs to have advanced performance, and to provide a manufacturing method therefor.

In order to fulfill the above-stated object, an organic semiconductor film of the present invention includes an organic conductive high polymer compound, which shows two or more spectral peaks in a wavelength region of 300 to 800 nm by measurement of a visible and ultraviolet absorption spectrum method in a solid state.

With the above-stated configuration, the organic semiconductor film of the present invention can be used for an electron device or the like, and especially when it is used for an organic TFT, an advanced TFT can be obtained.

### DESCRIPTION OF DRAWINGS

FIG. 1 is a schematic diagram of an organic TFT in Examples and Comparative examples.

FIG. 2 shows visible/ultraviolet absorption spectra of P3HT in a state of solution that is used for Example 1 and the Comparative Example.

FIG. 3 shows visible/ultraviolet absorption spectra of organic semiconductor films in Example 1 and the Comparative Example.

FIG. 4 is a graph showing carrier mobility of the organic semiconductor films in Example 1 and the Comparative Example.

FIG. 5 is a schematic diagram showing an estimated mechanism of visible/ultraviolet absorption spectral variation in an organic conductive high-polymer compound solution.

FIG. 6 is a schematic diagram showing an estimated mechanism of a relationship between visible/ultraviolet absorption spectral variation in an organic conductive high-polymer compound solution and carrier mobility variation of an organic semiconductor film.

FIG. 7 is a schematic diagram showing an estimated mechanism of a relationship between a molecular weight distribution range of an organic conductive high-polymer compound and carrier mobility.

FIG. 8 is a graph showing carrier mobility of organic semiconductor films in Examples 1 and 2 and the Comparative Example.

FIG. 9 is a graph showing XRD spectra of organic semiconductor films concerning organic TFTs in Examples 1 and 2.

FIG. 10 is a cross-sectional view schematically showing one example of an assumed structure of a part of an organic TFT.

### DESCRIPTION OF THE INVENTION

The inventors of the present invention found that when an organic semiconductor film made of an organic conductive high polymer compound shows two or more spectral peaks in a visible/ultraviolet absorption spectrum (also called an ultraviolet and visible absorption spectrum or a UV/VIS spectrum), the properties such as carrier mobility are improved as compared with those showing only one spectral peak. The mechanism of the correlation between visible/ultraviolet absorption spectra and carrier mobility is uncertain, but this might be considered to be related to the alignment of organic conductive high polymer compound molecules in an organic semiconductor film, which will be described below. When organic conductive high-polymer compound molecules are aligned in an irregular state in an organic semiconductor film, such a state makes it difficult for electrons to move among principal chains (among molecules), so that only one spectral peak is shown. On the other hand, when molecules are aligned regularly so that principal chains of the organic conductive high polymer compound molecules are arranged substantially in parallel, π conjugate is widened so that electrons are able to move easily among the principal chains (among molecules). Along with such ease for electrons moving, the carrier mobility would be improved, and concurrently new absorption would occur in a visible/ultraviolet absorption spectrum, thus showing two or more spectral peaks. As stated above, there is already a study being done for improving the carrier mobility of an organic semiconductor film in terms of the structure of molecules making up an organic semiconductor film. However, even in the case of materials having similar molecular structures, their visible/ultraviolet absorption spectral states are different in some cases, and the inventors of the present invention firstly studied that the carrier mobility further can be enhanced in accordance with the spectral state. As a result of the study based on these findings, according to the present invention, an organic semiconductor film whose carrier mobility could be enhanced more than the conventional one could be obtained.

Note here that a “visible/ultraviolet absorption spectral method in a solid state” with respect to the organic semiconductor film in the present invention refers to a method of measuring visible/ultraviolet absorption spectra in a film state (solid state) that is not subjected to an operation such as dissolving the organic semiconductor film into a solvent. More specifically, as the organic semiconductor film, a thin film that is the same as the above-stated organic semiconductor film is formed on a glass substrate (thickness: 1.0 mm), and the measurement is conducted concerning a wavelength region from ultraviolet to visible light (300 to 800 nm) at room temperature and atmospheric pressure using a UV/visible spectrophotometer (produced by JASCO Corporation, trade name: ultraviolet/visible/near-infrared spectrophotometer V-570). The measurement is conducted in 1 nm wavelength intervals, and a reference (the above-stated glass substrate without an organic semiconductor film formed thereon) also is measured. If such measurement of a film shows two or more peaks, the film can satisfy the requirements of the present invention. Although the film thickness of the thin film is not limited especially because it does not affect the number of the spectral peaks, it may be for example 100 to 200 nm.

Although the intensities and the wavelengths of the above-stated two or more spectral peaks in the organic semiconductor film of the present invention are not limited especially, it is preferable that the intensity of a peak on the shortest wavelength side is larger than or equal to intensities of any other peaks, for example. For instance, it is preferable that the peak on the longest wavelength side exists in the wavelength region of 550 to 800 nm, and for instance it is preferable that the peak on the shortest wavelength side exists in the wavelength region of 350 to 575 nm and at least one of the other peaks has a wavelength longer by 50 nm or more than the wavelength of the peak on the shortest wavelength side.

The above-stated organic conductive high polymer compound preferably is polythiophene represented by the following formula (I) in terms of higher carrier mobility or the like.

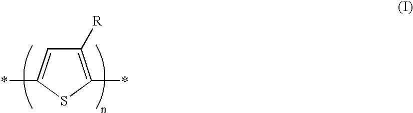

In formula (I), R denotes a hydrogen atom or an arbitrary substituent, which is not limited especially, but preferably is a substituent that does not impair the properties required for organic semiconductor. Herein, n denotes a degree of polymerization. In formula (I), preferably, R is at least one selected from the group consisting of a hydrogen atom, a substituted or a not-substituted alkyl group and a substituted or a not-substituted carbocyclic ring. More preferably, the alkyl group is a straight or a branched alkyl group with a carbon number of 1 to 12, and more preferably, the carbocyclic ring is a saturated or an unsaturated carbocyclic ring with 3-20 ring carbon atoms, and still more preferably is a monocyclic or a condensed ring. The above-stated alkyl group may be at least one selected from the group consisting of a methyl group, an ethyl group, a propyl group, a butyl group, a pentyl group, a hexyl group, an octyl group, a decyl group and a dodecyl group, and they may be in a straight-chain or in a branched-chain. The alkyl group, particularly preferably, is a straight-chain or a branched-chain alkyl group having a carbon number of 6 or more, which may be for example at least one selected from the group consisting of a hexyl group, an octyl group, a decyl group and a dodecyl group and they may be in a straight-chain or in a branched-chain. Herein, this exemplary description concerning the alkyl group of “may be in a straight-chain or in a branched-chain” means that, for example, the “propyl group” includes both of a n-propyl group and an isopropyl group, the “butyl group” includes a n-butyl group, a sec-butyl group, an isobutyl group and a tert-butyl group. Still more preferably, the carbocyclic ring is a benzene ring (phenyl group). More preferably, the substituent on the alkyl group or on the carbocyclic ring is at least one selected from the group consisting of halogen, a hydroxy group, a mercapto group, a carboxy group and a sulfo group. In the above formula (I), when R is a n-hexyl group, for example, an organic semiconductor film with particularly favorable properties can be obtained. However, the suitable polythiophene is not limited to this, and various polythiophene can be used. Incidentally, the polythiophene having a n-hexyl group as R in formula (I) is called poly (3-hexylthiophene), P3HT, etc.

In the above-stated formula (I), the degree of polymerization n is not limited especially, and an integer from 50 to 1,200 is preferable, for example. Further, in the above-stated formula (I), the molecular weight preferably is 10,000 to 200,000. In the case of a hexyl group as R, the degree of polymerization preferably is 55 to 1,200, and in the case of a dodecyl group as R, the degree of polymerization preferably is 50 to 1,050. Furthermore, the molecular weight distribution range Mw/Mn preferably ranges from 1.00 to 1.85. The Mw/Mn is obtained by dividing a weight-average molecular weight Mw by the number-average molecular weight Mn. This is because the properties of the organic semiconductor film become more favorable. The lower limit value of the molecular weight distribution range Mw/Mn is not limited especially. Ideally, this value is closer to 1, and may be 1.51 or more, for example. More preferably, the weight-average molecular weight Mw of the organic conductive high polymer compound ranges from 41,000 to 55,000, and the number-average molecular weight Mn is 27,150 or more, for example. In this case, although the upper limit value of the number-average molecular weight Mn is not limited especially, this may be a value not exceeding the value of the weight-average molecular weight Mw and may be 33,200 or less, for example. Note here that, in the organic semiconductor film of the present invention, the values of the weight-average molecular weight Mw and the number-average molecular weight Mn of the organic conductive high polymer compound are obtained by the measurement of 0.05 to 1.0 weight % concentration (e.g., 0.08 weight % concentration) of the organic conductive high polymer compound solution through Gel Permeation Chromatography (GPC) by an instrument produced by Viscotek Corporation, Model 300 TDA-Triple mode (trade name). The following shows one example of the detailed measurement conditions: as a mobile phase solvent, chloroform or THF may be used, and a column used may be TSKgel GMH_{XL} (two of them are connected for use, each having a length of 30 cm and an inner diameter of 7.8 mm). The temperature may be at 40° C. (both for column and detector), and the concentration of the organic conductive high polymer compound solution may be 0.08 weight % (n the case of using THF as a solvent, 0.69 mg of organic conductive high polymer compound per 1 mL (0.8892 g) of the solvent (THF)). The measurement can be conducted with the amount of the organic conductive high polymer compound solution of 100 μL and the flow velocity of 1.0 mL/min.

Preferably, the carrier mobility of the organic semiconductor film of the present invention is 10⁻⁴ cm²/V·s or more, for example, and more preferably is 10⁻² cm²/V·s or more. The upper limit value of the carrier mobility is not limited especially, and a higher value is better. This may be 10⁻¹ cm²/V·s or less, for example. The carrier mobility can be measured by the method described in Examples described later, for example.

When in the X-ray diffraction (XRD) spectral diagram, two points at the intersections of a peak-existing portion and a non-existing portion are connected by a straight line, and assuming that a relative intensity of diffraction X-ray at the peak vertex is i and a relative intensity of diffraction X-ray at a point on the straight line where a scattering angle 2θ is equal to the peak vertex is i₀, i/i₀ of the organic semiconductor film of the present invention preferably is 1.6 or more. More specifically, a larger i/i₀ value shows the organic conductive high polymer compound molecules aligned more regularly in the organic semiconductor film, and therefore a larger i/i₀ value can be considered favorable in terms of the improvement of the carrier mobility, etc. Note here that the value of i/i₀ is obtained by the measurement using an automatic X-ray diffraction apparatus named RINT-TF-PC (trade name) produced by Rigaku Corporation. The value of i/i₀ more preferably is 1.8 or more. Although the upper limit of the i/i₀ value is not limited especially, this may be 3.6 or less, for example.

An electron device of the present invention has high performance, because it includes the organic semiconductor film of the present invention. The uses of the electron device are not limited especially, and this device preferably is used for a thin film transistor (TFT), for example. Further, the electron device of the present invention is not limited especially and may have any desired structure, as long as it includes the organic semiconductor film of the present invention. For instance, a structure similar to a conventional one can be used appropriately. As one example of the structure of the electron device, the organic semiconductor film may be formed on an insulation layer. In such a case, a face of the insulation layer at which the insulation layer contacts with the organic semiconductor film preferably has a contact angle with respect to water of 13° or less. A smaller contact angle means a larger wettability with respect to water and other liquids, and therefore this is favorable in terms of the improvement of adhesiveness with the organic semiconductor film, and moreover in terms of the improvement of the carrier mobility, etc. The lower limit value of the contact angle is not limited especially, and this may be 0.1° or more, for example. Note here that the value of the contact angle is obtained by the measurement using Model G-1 (trade name) by ERMA Inc.

The following describes a manufacturing method of an organic semiconductor film of the present invention.

As stated above, concerning the properties such as carrier mobility of an organic semiconductor film of an organic TFT, numerous studies have been made for the relationship with organic semiconductor materials and the structure of organic TFTs. However, specific proposals for the relationship with the formation process have not been made so much. Therefore, there has been a demand for, by clarifying the relationship between the carrier mobility and the formation process of an organic semiconductor film, realizing higher carrier mobility and realizing a formation process for more stable carrier mobility in combination with the use of an effective organic semiconductor material. Then, as a result of keen examination, the inventors of the present invention newly found the manufacturing method of the present invention described as follows. Note here that although the manufacturing method of the present invention can be used for the manufacturing of any organic semiconductor film, this method is suitable for manufacturing the organic semiconductor film of the present invention. The manufacturing method of the organic semiconductor film of the present invention is not limited especially, and such a film can be manufactured by any method. However, it is preferable that the organic semiconductor film of the present invention is manufactured by the following manufacturing method of the present invention.

A first manufacturing method of the present invention is for manufacturing an organic semiconductor film, and includes the steps of: forming a solution in a thin film form, the solution containing an organic conductive high polymer compound, and showing two or more spectral peaks in a wavelength region of 300 to 800 nm by measurement using a visible and ultraviolet absorption spectral method; and drying the solution formed in the thin film form. The organic conductive high polymer compound preferably is polythiophene represented by the above-stated formula (I). In formula (I), the definition for R and n is as stated above. Preferable examples of R and a preferable range of n also are as stated above. Incidentally, concerning this manufacturing method, there is no need to measure visible/ultraviolet absorption spectra of the solution in the state of the concentration during the manufacturing of the organic semiconductor film. If a solution shows two or more spectral peaks in a wavelength region of 300 to 800 nm when its visible/ultraviolet absorption spectrum is measured under the following conditions, the solution can be considered as one that can be used for the first manufacturing method of the present invention. That is, as the measurement conditions, a UV/visible spectrophotometer (produced by JASCO Corporation, trade name: ultraviolet/visible/near-infrared spectrophotometer V-570) and a glass cell (optical length: 1.0 cm) are used. A solvent is used that is used for manufacturing of the organic semiconductor film, and the concentration of the solution is 0.01 weight %. The measurement using a reference liquid (the same liquid as the above-stated solution other than not including the organic conductive high polymer compound, but made of an organic solvent only) concurrently is conducted, and the measurement is conducted for the wavelength region from ultraviolet to visible light (300 to 800 nm) in 1 nm wavelength intervals at room temperature and atmospheric pressure. Herein, these measurement conditions are just one example of the measurement conditions for judging the suitability of the organic conducive high polymer compound solution, and the first manufacturing method of the present invention is not limited to the manufacturing method using these measurement conditions.

The reasons for such a manufacturing method enabling the manufacturing of an organic semiconductor film having high and stable carrier mobility have not become dear completely. However, the following mechanism might be considered.

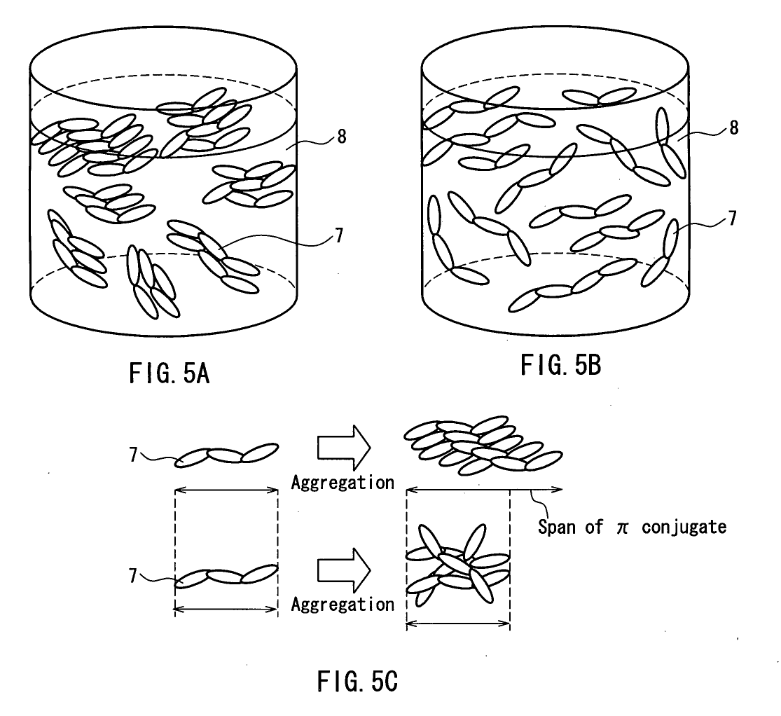

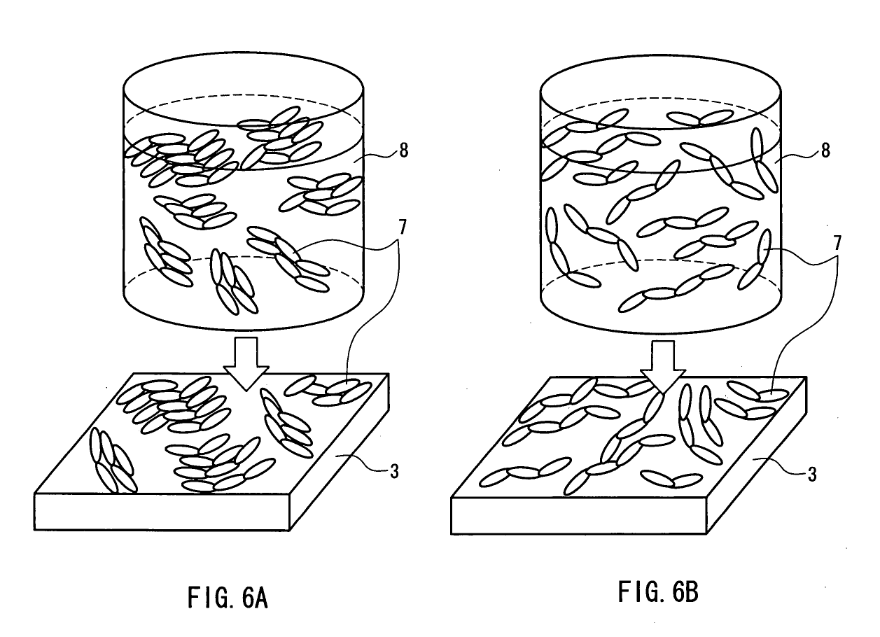

FIGS. 5 and 6 schematically show the mechanism, which simply show one example of the estimated mechanism and are not intended to limit the present invention. FIGS. 5A and B schematically show the state of molecules in the organic conductive high polymer compound solution, and FIG. 5C shows the aggregation state of the molecules. FIGS. 6A and B schematically show how the state of the molecules change when an organic semiconductor film is formed using the solutions shown in FIGS. 5A and B. In these drawings, numeral 7 denotes organic conductive high polymer compound molecules, 8 denotes the solution in which the molecules are dissolved, and 3 denotes the organic semiconductor film made up of the molecules 7. Conceivably, not only the state of the organic semiconductor film (solid state) formed using the organic conductive high polymer compound but also the state of the solution has a similar relationship to the above between the spectral peaks observed by the visible/ultraviolet absorption spectral method and the molecular alignment. That is, it can be considered that irregular molecular alignment leads to only one spectral peak, whereas regular alignment such that principal chains of the organic conductive high polymer compound molecules are arranged substantially in parallel leads to two or more peaks. Conceivably, in the solution showing two spectral peaks, a plurality of organic conductive high polymer compound molecules are aligned regularly so as to form an aggregation as shown in FIG. 5A and the upper portion of FIG. 5C, and therefore the molecules are dispersed in the solution while keeping such regular alignment. On the other hand, it can be considered that, in the. solution showing one spectral peak, the molecules are dispersed in pieces as shown in FIG. 5B, and even if they are in an aggregation state, the aggregation is in an irregular alignment such that makes it difficult to move electrons among the principal chains as shown in the lower portion of FIG. 5C. Conceivably, when the organic conductive high polymer compound molecules are aligned regularly in the solution as shown in FIG. 6A, the organic semiconductor film formed using the solution also has a regular alignment of the organic conductive high polymer compound molecules. Thus, electrons are able to move easily among principal chains (among molecules) for the above-stated reason, thus enhancing carrier mobility. On the other hand, when the organic conductive high polymer compound molecules are aligned irregularly in the solution as shown in FIG. 6B, the organic semiconductor film formed using the solution also has an irregular alignment of the organic conductive high polymer compound molecules. Incidentally, when electrons are able to move easily among principal chains (among molecules), the spectral peaks generally tend to be shifted to the long wavelength side slightly, which is not an absolute tendency, though.

In this manufacturing method, the intensities and the wavelengths of the above-stated two or more spectral peaks are not limited especially, and it is preferable that the intensity of a peak on the shortest wavelength side is larger than or equal to intensities of any other peaks, for example. For instance, it is preferable that the peak on the longest wavelength side exist in the wavelength region of 550 to 800 nm, and for instance it is preferable that the peak on the shortest wavelength side exists in the wavelength region of 300 to 500 nm and at least one of the other peaks has a wavelength longer by 100 nm or more than the wavelength of the peak on the shortest wavelength side. Note here that, in the solution state, the interaction between the organic conductive high polymer compound molecules is different from that in the solid state, and there also exists interaction between the organic conductive high polymer compound molecules and the solvent molecules, and therefore preferable peak wavelengths are slightly different from those in the solid state.

Next, a second manufacturing method of the present invention is for manufacturing an organic semiconductor film, and includes the steps of: forming a solution containing an organic conductive high polymer compound in a thin film form; and drying the solution formed in the thin film form. The organic conductive high polymer compound has a molecular weight distribution range Mw/Mn from 1.00 to 1.85, which is obtained by dividing a weight-average molecular weight Mw by a number-average molecular weight Mn. The organic conductive high polymer compound preferably is polythiophene represented by the above-stated formula (I). In formula (I), the definition for R and n is as stated above. Preferable examples of R and a preferable range of n also are as stated above. The lower limit value of the molecular weight distribution range Mw/Mn is not limited especially. Ideally, this value is closer to 1, and may be 1.51 or more, for example. More preferably, the weight-average molecular weight Mw of the organic conductive high polymer compound ranges 41,000 to 55,000, and the number-average molecular weight Mn is 27,150 or more, for example. In this case, although the upper limit value of the number-average molecular weight Mn is not limited especially, this may be a value not exceeding the value of the weight-average molecular weight Mw and may be 33,200 or less, for example. Note here that if an organic conductive high polymer compound has the value of Mw/Mn ranging from 1.00 to 1.85 under the conditions shown in Examples described later, the organic conductive high polymer compound can be considered as one that can be used for the second manufacturing method of the present invention. Herein, these measurement conditions are just one example of the measurement conditions for judging the suitability of the organic conducive high polymer compound, and the second manufacturing method of the present invention is not limited to the manufacturing method using these measurement conditions.

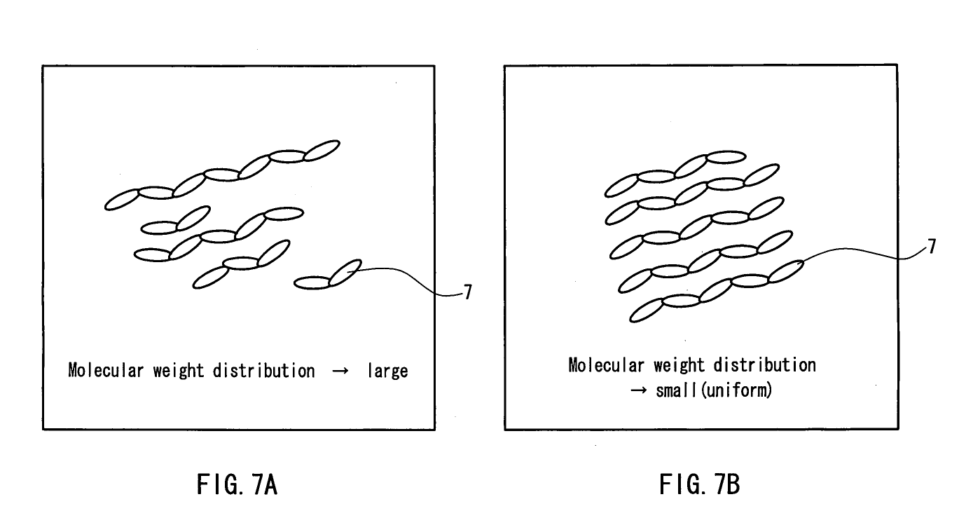

The reasons for such a decreased variation in the size of the organic conductive high polymer compound molecules enabling the manufacturing of an organic semiconductor film having high carrier mobility have not become clear completely. However, the following mechanism might be considered. FIG. 7 schematically shows the mechanism, which simply shows one example of the estimated mechanism and is not intended to limit the present invention. FIGS. 7A and B schematically show the alignment state of the molecules when the molecular weight distribution ranges are large and small, respectively, in the solution of organic conductive high polymer compound molecules. According to our estimation, the organic conductive high polymer compound molecules having an increased variation in size have a difficulty in aligning regularly in the solution as shown in FIG. 7A, whereas those having a decreased variation are easy to be aligned regularly so that their principal chains are aligned substantially in parallel as shown in FIG. 7B. As stated above, when the organic conductive high polymer compound molecules are aligned regularly in the solution, the organic semiconductor film formed using the solution also has a regular alignment of the organic conductive high polymer compound molecules. Therefore, it can be considered that electrons are able to move easily among principal chains (among molecules) for the above-stated reasons, thus improving the carrier mobility.

A method of adjusting the molecular weight and the molecular weight distribution range of the organic conductive high polymer compound is not limited especially, and the following are available, for example. Firstly, a so-called centrifuge separation method can be used, i.e., when a centrifugal force is applied by rotation to molecules having different molecular weights, molecules with larger molecular weights will be distributed at a more outer portion. By utilizing this property, molecules with desired molecular weights can be separated from molecules with inappropriate molecular weights. As another method, chromatography is available, i.e., a solution of the organic conductive high polymer compound is subjected to Gel Permeation Chromatography (GPC) or the like so as to separate molecules large in size from small ones. As still another method, a reprecipitation method is available, i.e., the method is a refining technology in which the organic conductive high polymer compound firstly is dissolved into a minimum amount of solvent (good solvent), which then is dropped to a solvent (poor solvent) having a low solubility with respect to the organic conductive high polymer compound so as to generate precipitation. However, the method for optimizing the molecular weight and the molecular weight distribution range is not limited to them, and any other method can be used. In addition, if a commercially available organic conductive high polymer compound can be used to obtain favorable results, such a compound may be used without any particular treatment applied thereto.

In the first and the second manufacturing methods of the present invention, in order to achieve still higher carrier mobility, the organic conductive high polymer compound solution preferably is allowed to stand still prior to the formation into a thin film form, and more preferably is allowed to stand still until the solution becomes gel. The time for allowing the solution to stand still is not limited especially, and 10 minutes or longer is preferable. The upper limit value of the time is not limited especially, and 60 minutes or shorter is preferable. The mechanism of further improving the carrier mobility by this method has not become clear. However, conceivably, the standing still of the solution leads to a regular alignment state of the organic conductive high polymer compound molecules, thus enabling a regular alignment state of the molecules in the organic semiconductor film as well, and such regular alignment state would be reflected in the good carrier mobility. The solution becomes gel in some cases while standing still, and such gelation also would result from the generation of microcrystals caused by the regular alignment of the organic conductive high polymer compound molecules. Even if the organic conductive high polymer compound solution is not kept standing still until it becomes gel, the effect of improving the carrier mobility can be obtained. However, it is preferable to allow the solution to stand still until it becomes gel, because a change in the state of the solution can be confirmed easily by visual inspection. Herein, since it is difficult to process the organic conductive high polymer compound solution in a gel state, it is more preferable to apply heat thereto again prior to the formation of a thin film form so as to bring it back in a liquid state.

In these first and second manufacturing methods of the present invention, the solvent of the organic conductive high polymer compound solution is not limited especially, and preferably includes at least one of aromatic hydrocarbon, halogenated aromatic hydrocarbon, aliphatic hydrocarbon and halogenated aliphatic hydrocarbon in terms of the solubility of the organic conductive high polymer compound or the like. More preferably, it includes at least one of benzene, toluene, o-xylene, m-xylene, p-xylene, chlorobenzene, o-dichlorobenzene, m-dichlorobenzene, p-dichlorobenzene, methylene chloride, chloroform, carbon tetrachloride and tetrachloroethylene.

Preferably, the first and the second manufacturing methods of the present invention further include the steps of preparing an insulator; and conducting a plasma etching treatment on a surface of the insulator. In these manufacturing methods, it is preferable to form the solution containing the organic conductive high polymer compound in a thin film form on the surface subjected to the plasma etching treatment, in terms of further improvement of the carrier mobility of the semiconductor film. The insulator is not limited especially, and this may be an insulation layer included in an electron device, for example, a gate insulation layer of a thin film transistor (TFT). The material for forming the insulator is not limited especially, and SiO₂, SiOₓ, SiNₓ, AlNₓ, polyimide, polyester, polymethylmethacrylate and the like are available.

The reason for further improvement in carrier mobility, etc., of the organic semiconductor film by the plasma etching treatment applied to the surface of the insulation layer has not become clear completely. However, this can be considered as follows. Herein, the following description simply shows one example of the estimated mechanism and is not intended to limit the present invention.

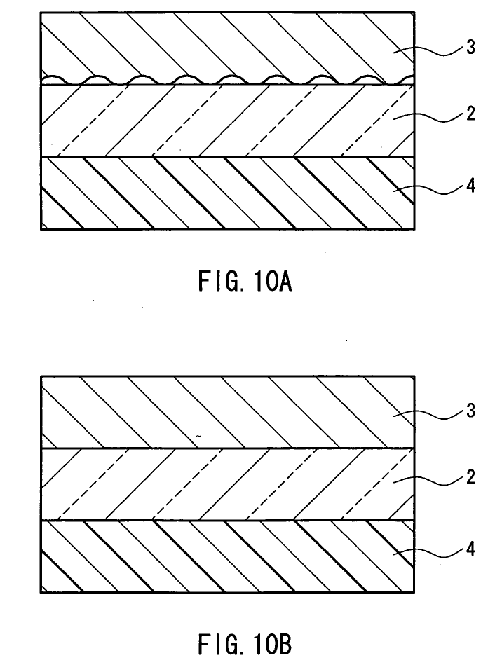

FIG. 10 is a cross-sectional view schematically showing an estimated structure of a part of an organic TFT including the above-stated organic semiconductor film. FIG. 10A shows the case where no plasma etching treatment is applied to the gate insulation layer, and FIG. 10B shows the case where a plasma etching treatment is applied to the gate insulation layer. As shown in these drawings, these organic TFTs are configured so that a gate insulation layer 2 is laminated on a gate electrode 4, on which an organic semiconductor film 3 further is laminated. In the case of FIG. 10B, the adhesiveness between the gate insulation layer 2 and the organic semiconductor film 3 further is improved as compared with the case of FIG. 10A. As the mechanism, it is estimated that the plasma etching treatment to the surface of the gate insulation layer 2 further improves the wettability, thus causing this improvement. That is, it can be considered that further improvement in the wettability of the surface makes the surface intimate with the organic conductive high polymer compound solution, and therefore when the solution is formed in a thin film form and is dried to form the organic semiconductor film 3, the adhesiveness with such organic semiconductor film 3 also can be improved. When the adhesiveness is improved in this way, the substantial contacting area between the gate insulation layer 2 and the organic semiconductor film 3 is increased more. As a result, it is estimated that a loss occurring when a gate voltage is applied to the organic semiconductor film 3 is reduced, thus leading to further improvement in the carrier mobility.

As another factor of improving the carrier mobility further, the following also can be estimated. That is, when the wettability of the surface of the gate insulation layer 2 is improved further as stated above, the surface of the organic semiconductor film 3 at which the organic semiconductor 3 contacts with the gate insulation layer 2 would have a more uniform structure. Then, the organic semiconductor film 3 attains the improvement of the regularity in the molecular alignment, e.g., the crystal alignment property (the degree of principal chain stacking), and as a result, it is estimated that the carrier mobility further is improved. Herein, the estimated mechanism for improving the carrier mobility resulting from the regular alignment of the organic conductive high polymer compound molecules is as stated above. In particular, in the case where the plasma etching treatment is conducted on the surface of the insulator in the manufacturing method of the present invention, a synergistic effect from the adjustment of Mw/Mn of the organic conductive high polymer compound or of the visible/ultraviolet absorption spectra of the solution can be expected. More specifically, because of this synergistic effect, the molecules of the organic conductive high polymer compound become particularly easy to be aligned regularly, and therefore the carrier mobility of the organic semiconductor film might be improved more significantly.

The conditions of the plasma etching treatment are not limited especially, and it is preferable that a distance between the surface and an electrode, the magnitude of an ion current, a processing time and the like are set appropriately with consideration given to the etching rate, the etching degree of the etched surface (engraving rate) and the like.

The gas used for the plasma etching treatment also is not limited especially, and oxygen, argon or the like is available, for example. The plasma etching treatment conducted in an atmosphere containing oxygen gas is particularly preferable in terms of further improvement in etching efficiency, a decrease in damage given to the surface of the insulator by etching, the carrier mobility of the organic semiconductor film and the like.

Note here that the relationship between the damage given to the surface of the insulator by etching and the carrier mobility of the organic semiconductor film can be considered as follows. That is, if the etching degree of the surface of the insulator is excessive (engraved too much), then the surface of the insulator becomes rough. As a result, it becomes difficult to align the molecules of the organic conductive high polymer compound regularly, which might impair the improvement in the carrier mobility of the organic semiconductor film. In the case of using oxygen gas, however, an appropriate etching degree can be obtained easily, and therefore the carrier mobility of the organic semiconductor film might be improved. Herein, this description also simply shows one example of the estimated mechanism and is not intended to limit the present invention.

In the first and the second manufacturing methods of the present invention, a method for forming the solution in a thin film form is not limited especially, and conventional methods such as a spin coating method, a cast method, a printing method including screen printing, gravure printing, an ink jet printing method, etc. can be used appropriately. Further the drying method also is not limited especially, and air-drying can suffice. However, in terms of the manufacturing efficiency, heat drying and vacuum drying are preferable, and a heating treatment and a vacuum treatment may be conducted at the same time for drying. The temperature, the pressure and the like during drying also are not limited especially, and similar conditions to conventional organic semiconductor film manufacturing can be applied appropriately.

A manufacturing method of an electron device of the present invention is for manufacturing an electron device including an organic semiconductor film manufactured by the first or the second manufacturing method of the present invention. According to this manufacturing method, an advanced electron device can be manufactured. The manufacturing method of an electron device of the present invention is not limited especially in other respects, and a similar method to a conventional electron device manufacturing method can be applied appropriately. The electron device is not limited especially, and a thin film transistor (TFT) is preferable, for example.

### EXAMPLES

A plurality of organic TFTs were manufactured, and the correlation between applied voltages and currents was examined. Then, carrier mobility for each was calculated for comparison. The organic TFTs were manufactured including different organic semiconductor films, and portions other than them were manufactured using exactly the same materials and having the same configuration. More specifically, as the organic semiconductor films, P3HT (poly (3-hexylthiophene)) was used for all TFTs, but their molecular weight distribution ranges and the like were varied for the respective TFTs.

### [Measurement Conditions, etc.,]

Visible and ultraviolet absorption spectra of the P3HT solution and the organic semiconductor films made from the solution were measured using a UV/visible spectrophotometer (produced by JASCO Corporation, trade name: ultraviolet/visible/near-infrared spectrophotometer V-570) at room temperature and atmospheric pressure. The spectra were measured for the wavelength region from ultraviolet to visible light (300 to 800 nm) in 1 nm wavelength intervals. A glass cell (optical length: 1.0 cm) was used for the measurement of the solution, and the measurement using a reference liquid (the same liquid as the above-stated solution except for not including PH3T but made of an organic solvent only) also was conducted. A solvent was used that was used for manufacturing the organic TFTs, and the concentration of the solution was 0.01 weight %. Meanwhile, an organic semiconductor film of 100 to 200 nm in thickness formed on a glass substrate (thickness: 1.0 mm) was used for the measurement of visible/ultraviolet absorption spectra of the organic semiconductor film, and the measurement was conducted also with a reference (the glass substrate without an organic semiconductor film formed thereon). The molecular weight of P3HT was measured using a P3HT solution with a concentration of 0.05 to 1.0 weight % (solvent was chloroform or THF) through Gel Permeation Chromatography (GPC) by the instrument produced by Viscotek Corporation, Model 300 TDA-Triple mode (trade name). The concentration of the sample solution was 0.05 to 1.0 weight % as described above, and as one example, 0.69 mg (0.08 weight %) of the organic conductive high polymer compound per 1 mL (0.8892 g) of the solvent (THF) was used for the measurement. A mobile phase solvent was chloroform or THF, and a column was TSKgel GMHXL (two of them are connected for use, each having a length of 30 cm and an inner diameter of 7.8 mm). The measurement was conducted at a temperature of 40° C. (both for column and detector), and the amount of the sample solution was 100 μL and the flow velocity was 1.0 mL/min. As P3HT, the regioregular product produced by Sigma-Aldrich Corporation was purchased, whose molecular weight and molecular weight distribution range were adjusted appropriately before use by the above-stated centrifuge separation method, chromatography method or reprecipitation method. Incidentally, the “regioregular”, according to the specifications of the products by Sigma-Aldrich Corporation, refers to a high degree of positional regularity of hexyl groups in P3HT.

Plasma etching was conducted using an ion sputtering apparatus named E-1030 (trade name) produced by Hitachi, Ltd, and the etching was conducted in an oxygen (O₂) gas atmosphere with a distance between the surface to be etched and an electrode set at 35 mm and with an ion current applied of 15 mA for the processing time of 100 seconds. The measurement of wettability (contact angle) was conducted using Model G-1 (trade name) by ERMA Inc. X-ray diffraction (XRD) spectrum was measured using an automatic X-ray diffraction apparatus named RINT-TF-PC (trade name) produced by Rigaku Corporation, in which Cu was used for the anticathode.

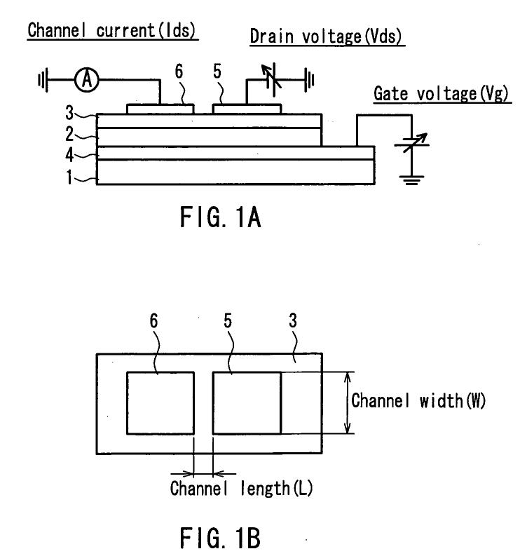

FIG. 1 shows the structure of an organic TFT manufactured in this example. As stated above, a plurality of organic TFTs were manufactured, all of which had a similar structure. FIG. 1A is a side view of this organic TFT and FIG. 1B is a top view of the same. The following describes the structure of this organic TFT based on these drawings. As illustrated, this organic TFT includes a substrate 1, a gate insulation layer 2, an organic semiconductor film (organic semiconductor layer) 3, a gate electrode 4, a drain electrode 5 and a source electrode 6 as major constituent elements. On the substrate 1 is stacked the gate electrode 4, and on a part of the gate electrode 4 is stacked the gate insulation layer 2, on which the organic semiconductor film 3 further is stacked. On the organic semiconductor film 3 is stacked the drain electrode 5 and the source electrode 6 in different regions so that the drain electrode 5 and the source electrode 6 are arranged to be kept from contact with each other. Note here that although FIG. 1 shows the structure where the gate electrode 4 is stacked on the substrate 1 as stated above for convenience in description, the substrate 1 and the gate electrode 4 were integrated in the organic TFTs actually manufactured in this example, and a portion on the substrate 1 where the gate insulation layer 2 was not stacked doubled as the function of the gate electrode 4.

### [Manufacturing of Organic TFTs]

More specifically, the organic TFT shown in FIG. 1 was manufactured as follows. As stated above, a plurality of organic TFTs were manufactured, and they were manufactured by a similar method, although there are partial exceptions. Thus, the following description is for all of them.

That is, firstly, a silicon (Si) board with a low resistivity (0.1 to 10 Ωcm) was prepared as the substrate 1 doubling as the gate electrode 4. Next, the top face of the substrate 1 was partially subjected to a thermal oxidation treatment to form a SiO₂ layer of 300 nm in thickness, which was the gate insulation layer 2. In the other portion of the top face of the substrate 1 that was not subjected to the thermal oxidation treatment, silicon was exposed, at which an electric contact (connection for measurement) of the gate electrode 4 was obtained. A conductive paste (not illustrated) was provided at the electric contact (connection for measurement). Herein, instead of the thermal oxidation treatment only for a part of the top face of the substrate 1 (silicon board) as stated above, a thermal oxidation treatment may be applied to the entire top face of the substrate 1 so as to form a SiO₂ layer of 300 nm in thickness, followed by the removal of the SiO₂ layer partially by etching, grinding or the like so as to enable the exposure of silicon (Si) substrate there, thus providing an electric contact (connection for measurement) with the gate electrode 4.

Meanwhile, P3HT (poly (3-hexylthiophene)) was dissolved in an organic solvent to prepare the solution for forming the organic semiconductor film 3. As the organic solvent, chloroform, chlorobenzene, benzene, paraxylene or the mixed solvent thereof was used, and the concentration of the solution was set at 0.5 to 1.0 weight % in terms of the P3HT concentration. As one example, 1 ml (1.484 g) of the solvent (chloroform) was used with respect to 10 mg of P3HT for the preparation. Next, this solution was subjected to an ultrasonic treatment for 30 to 90 minutes so as to dissolve P3HT sufficiently, which then was filtered through a filter with the mesh size of 0.1 to 0.2 μm so as to remove the insoluble content completely. Then, this solution was applied to the top face of the gate insulation layer 2 by spin coating. The rotational speed of the substrate during this spin coating was 2,000 rpm, which was conducted for 20 seconds. Then, this was heated and dried at 50 to 120° C. for 60 minutes, so as to form the organic semiconductor layer 3 with a thickness of 100 to 200 nm. Further, an Au electrode film of about 20 to 100 nm in thickness was formed at two positions on the organic semiconductor layer 3 by vacuum evaporation using a shadow mask and a wire, which became the drain electrode 5 and the source electrode 6. In this way, the sought organic TFT was obtained. The drain electrode 5 and the source electrode 6 were formed to have a channel width W=3 mm and a channel length L=50 μm.

As for some of the thus manufactured plurality of organic TFTs, the weight-average molecular weight Mw, the number-average molecular weight Mn and the molecular weight distribution range Mw/Mn of P3HT used for their organic semiconductor layers 3 are shown in the following Table 1. In the following, the manufactured organic TFTs having the molecular weight distribution range of 1.85 or less are called Example 1 and those exceeding 1.85 are called Comparative example.

TABLE 1

| | Mw | Mn | Mw/Mn |
|---|---|---|---|
| Comparative | 55,000 | 25,000 | 2.20 |
| Examples | 55,000 | 27,100 | 2.03 |
| Examples | 55,000 | 29,700 | 1.85 |
| | 53,400 | 33,200 | 1.61 |
| | 41,000 | 27,150 | 1.51 |

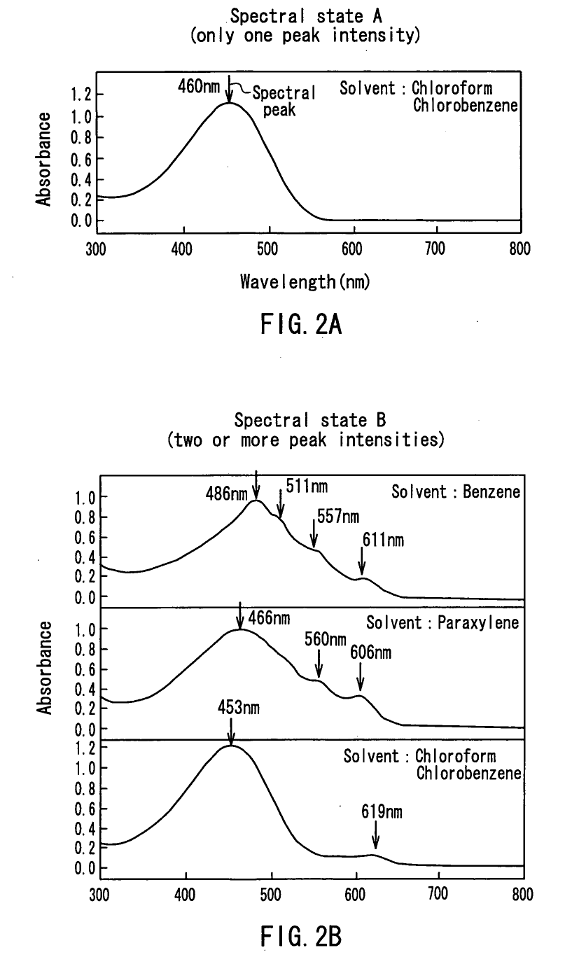

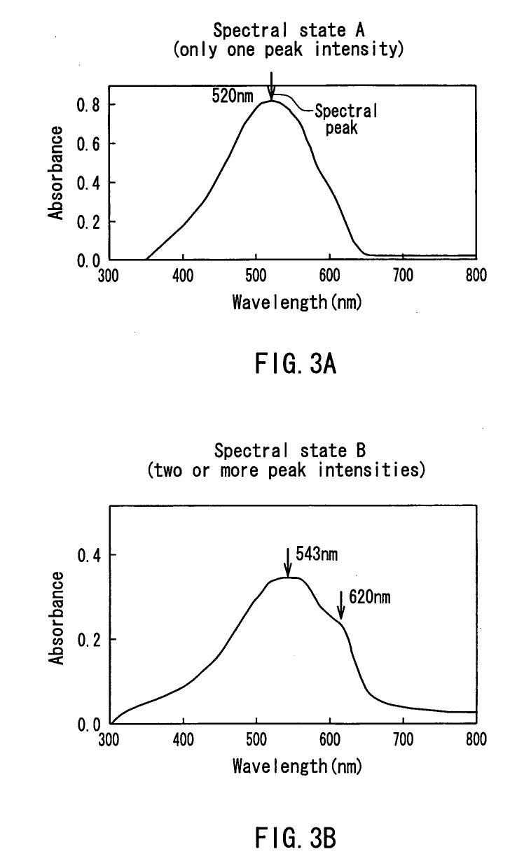

For each of the organic TFTs in Example 1 and Comparative example, the P3HT solution for forming the organic semiconductor layer 3 was filtered so as to remove the insoluble content completely. Thereafter, visible/ultraviolet absorption spectra were measured before the formation of the organic semiconductor layer 3. At this time, since the solution was too thick to perform the measurement, a part of the solution was extracted and diluted to the above-stated predetermined concentration (0.01 weight %) before measurement. FIG. 2 shows some of the measurement results. While the P3HT solution of Comparative example showed only one peak (called spectrum state A) as shown in FIG. 2A, all of the P3HT solutions in Example 1 showed two or more peaks (called spectrum state B) as shown in FIG. 2B. Also, visible/ultraviolet absorption spectra were measured in the solid state after the formation of the organic semiconductor layer 3. FIG. 3 shows one example of the measurement results. While the P3HT solution of Comparative example showed only one peak (called spectrum state A) as shown in FIG. 3A, all of the P3HT solutions in Example 1 showed two or more peaks (called spectrum state B) as shown in FIG. 3B.

### [Voltage-Current Characteristics]

Voltage-current characteristics were evaluated concerning the thus manufactured organic TFTs. That is, firstly, a gate voltage V_{g} and a drain voltage V_{ds} were applied to the organic TFTs as shown in FIG. 1, and a channel current I_{ds} was measured. Further, while V_{g} and V_{ds} were varied, the carrier mobility was calculated from the relationship between V_{g} and I_{ds} in the saturation region. Herein, the saturation region refers to the region where the value of V_{ds} is a certain value or more, and in this region, the value of I_{ds} becomes constant irrespective of the value of V_{ds}.

The carrier mobility in the saturation region was calculated based on the following theoretical formula. That is, it is known that V_{g} and I_{ds} in the saturation region and the carrier mobility have the relationship represented by the following formula [1]:

I_{ds}=(μ·C_{IN}·W(V_{g}−V_{TH})²)/2L [1]

In the formula [1], I_{ds} denotes a channel current (A), V_{g} denotes a gate voltage (V), μ denotes carrier mobility (cm²/V·s), C_{IN} denotes a capacitance of the gate insulation layer per unit area, W denotes a channel width, V_{TH} denotes a threshold voltage of the gate when a channel starts to be formed, and L denotes a channel length. In this example, C_{IN}=1.0×10⁻⁸ (F/cm²), and as stated above, W=_{0.3} (cm) and L=5.0×10⁻³ (cm). Herein, the transformation of the above formula [1] leads to the following formula [2]. By substituting the above-stated values of W, L and C_{IN}, the measurement values of V_{g} and I_{ds} and the value of V_{TH} in this formula [2], carrier mobility μ(cm²/V·s) was obtained. Herein, as the above-stated value of V_{TH}, the apparent V_{TH} was used, obtained from a contact point with I_{ds}=0 (intercept with the gate voltage axis) in the graph representing the relationship between V_{g} and the square root of I_{ds}, the contact point being obtained by extending the straight-line section showing the saturation region (n the saturation region, V_{g} and the square root of I_{ds} have a substantially linear relationship).

μ=(2L·I_{ds})/(C_{IN}·W(V_{g}−V_{TH})²) [2]

Note here that, in this example, there were slight differences in thickness of the organic semiconductor layers 3, the drain electrode 5 and the source electrode 6 among the respective TFTs as stated above. However, these differences do not affect the carrier mobility.

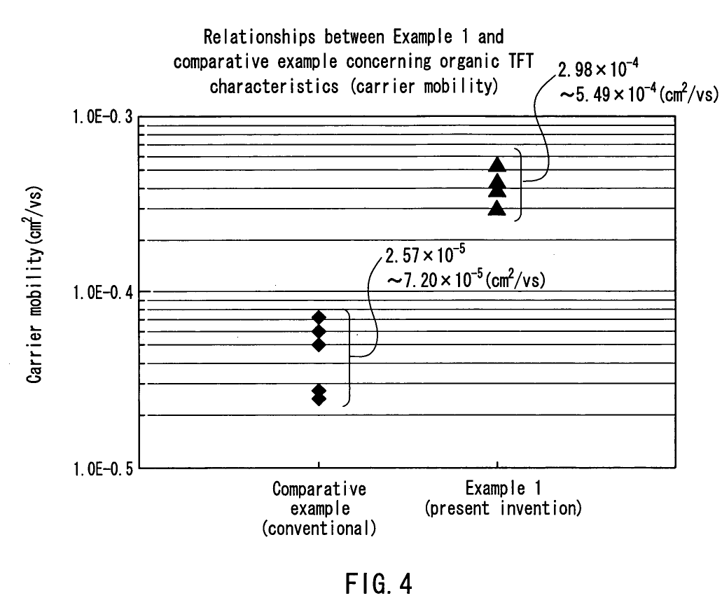

In this way, carrier mobility was calculated for each of the organic TFTs in Example 1 and Comparative example. FIG. 4 is a graph showing the results collectively. As shown in this graph, the organic TFTs of Comparative example have the carrier mobility ranging from 2.57×10⁻⁵ to 7.20×10⁻⁵ (cm²/V·s), whereas those of Example 1 were improved remarkably to 2.98×10⁻⁴ to 5.49×10⁻⁴ (cm²/V·s). In this way, it was found that even when materials having exactly the same molecular structure are used, carrier mobility can be improved 10 times or more by appropriately setting the molecular weight distribution range and the state of visible/ultraviolet spectra.

### [Manufacturing of Organic TFTs Using Plasma Etching and Their Performance Evaluation]

Next, using P3HT similar to Example 1 (having molecular weight distribution range of 1.85 or less), organic TFTs were manufactured in a similar manner to Example 1, except that a plasma etching treatment was conducted on the top face of the gate insulation layer 2 prior to the application of a P3HT solution. The plasma etching treatment was performed under the above-stated conditions.

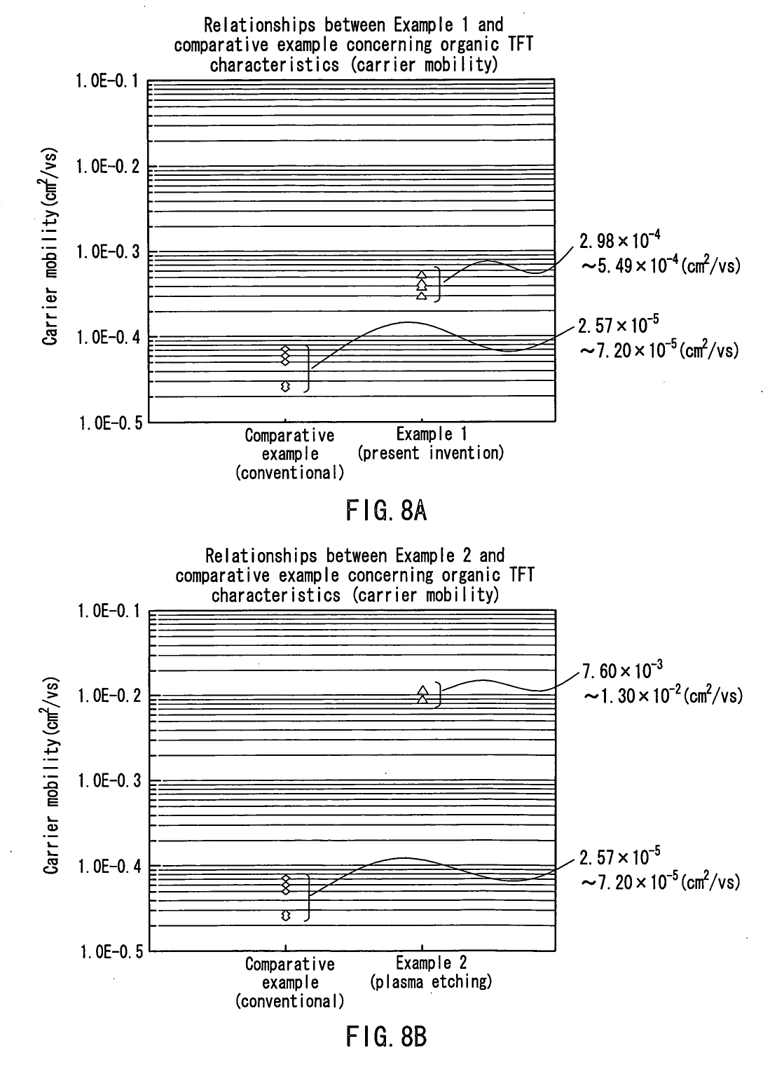

Hereinafter, a plurality of the thus manufactured organic TFTs will be called Example 2. Similarly to Example 1 and Comparative example, their voltage-current characteristics were evaluated and the carrier mobility for each was calculated. FIG. 8A is a graph showing the carrier mobility of each of the organic TFTs in Example 1 and Comparative example again, and FIG. 8B is a graph collectively showing the carrier mobility of each of the organic TFTs in Example 2 and Comparative example. As shown in these graphs, the organic TFTs of Comparative example have the carrier mobility ranging from 2.57×10⁻⁵ to 7.20×10⁻⁵ (cm²/V·s) and those of Example 1 range from 2.98×10⁻⁴ to 5.49×10⁻⁴ (cm²/V·s), whereas those of Example 2 were further remarkably improved to 7.60×10⁻³ to 1.30×10⁻² (cm²/V·s). In other words, the organic TFTs in Example 1 showed high carrier mobility that was 10 times or more those of the organic TFTs of Comparative example, and the organic TFTs in Example 2 showed considerably high carrier mobility that was 10 times to several tens of times those of Example 1.

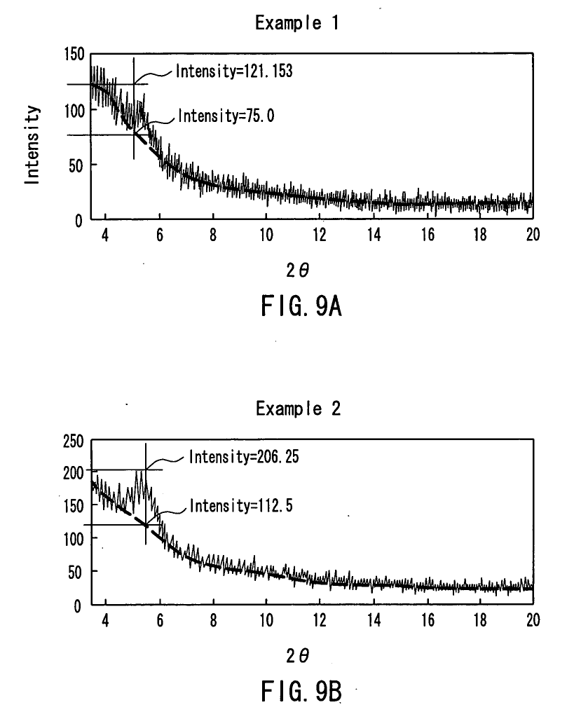

Further, concerning the organic TFTs in Example 1 and Example 2, XRD spectra of their organic semiconductor films 3 were measured. FIG. 9A is a graph showing the XRD spectrum of the organic semiconductor film 3 in one of the organic TFTs in Example 1, and FIG. 9B is a graph showing the XRD spectrum of the organic semiconductor film 3 in one of the organic TFTs in Example 2. In both graphs, the vertical axis shows a relative intensity of diffraction X ray. The horizontal axis shows a scattering angle 2θ expressed in the unit of degree (°). As shown in these graphs, clear peaks are shown at around 5.5° of the scattering angle 2θ, and it can be understood that the P3HT molecules are aligned regularly. Herein, the broken lines in these graphs show a spectrum by approximations assuming that peaks do not exist in these graphs. From these graphs, when i and i₀ were derived for both Examples and i/i₀ was calculated, they were i=121.153, i₀=75.0 and i/i₀=1.6154 for Example 1 and i=206.25, i₀=112.5 and i/i₀=1.8333 for Example 2. That is to say, in the organic semiconductor film of Example 2, the P3HT molecules were aligned still more regularly than in Example 1. Note here that i and i₀ are defined as stated above. The XRD spectrum in FIG. 9A or FIG. 9B shows the measurement of one of the plurality of organic TFTs manufactured in Example 1 or Example 2. However, when XRD was measured similarly for the remaining organic TFTs and i/i₀ was calculated therefor, the organic TFTs in Example 1 other than the TFT shown in FIG. 9A had substantially the same i/i₀ value as that of FIG. 9A, and the organic TFTs in Example 2 other than the TFT shown in FIG. 9B had substantially the same i/i₀ value as that of FIG. 9B.

Further, concerning Example 1 and Example 2, prior to the formation of the organic semiconductor films, their wettability (contact angle) was measured by dropping water on the surface of the gate insulation layers. As a result, the contact angle was 47° in Example 1 and 13° or less in Example 2. That is, it was confirmed that the wettability of Example 2, subjected to the plasma etching treatment, was enhanced remarkably as compared with Example 1. Incidentally, the contact angle of 13° is the lower limit value for the wettability measurement by the above-stated Model G-1 (trade name) by ERMA Inc.

Herein, 1.0 weight % benzene solution of P3HT was subjected to an ultrasonic treatment so as to dissolve P3HT well, which was then filtered with a filter so as to remove the insoluble content completely. After letting this resultant solution stand still at a room temperature for 10 to 60 minutes, an organic semiconductor film 3 was formed, and carrier mobility and visible/ultraviolet absorption spectra were measured in a similar manner to the above. As a result, as compared with the case of promptly forming before letting the solution stand still, the carrier mobility was improved, and (two) spectral peaks were shown more clearly, which were shifted to a longer-wavelength side. Incidentally, if the P3HT solution becomes a gel or in a semi-solid state during the still standing, heat may be applied thereto at about 50 to 100° C. so as to bring it back in a liquid state, and then the organic semiconductor film 3 can be formed, whereby favorable carrier mobility and spectral peaks were able to obtained as stated above.

### INDUSTRIAL APPLICABILITY

As described above, according to the present invention, an organic semiconductor film that can be used for an electron device or the like, particularly can be used for organic TFTs so as to allow the TFTs to have advanced performance can be provided, and a manufacturing method therefor also can be provided. With the use of the present invention, even when materials having exactly the same molecular structure are used, carrier mobility can be improved 10 times or more by appropriately setting the molecular weight distribution range and the state of visible/ultraviolet spectra, and therefore the present invention can contribute significantly to higher performance of electron devices.

1. An organic semiconductor film, comprising an organic conductive high polymer compound,
wherein the film shows two or more spectral peaks in a wavelength region of 300 to 800 nm by measurement of a visible and ultraviolet absorption spectrum method in a solid state.

2. The organic semiconductor film according to claim 1, wherein the organic conductive high polymer compound is polythiophene represented by the following formula (I): 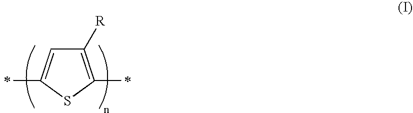
where in the formula (I) R is a hydrogen atom or an arbitrary substituent, and n denotes a degree of polymerization.

3. The organic semiconductor film according to claim 1, wherein the organic conductive high polymer compound is polythiophene represented by the following formula (I) 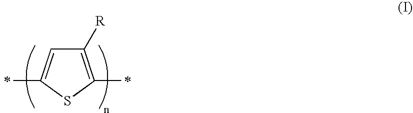
where in the formula (I) R is at least one selected from the group consisting of a hydrogen atom, a substituted or a not-substituted alkyl group and a substituted or a not-substituted carbocyclic ring, and n denotes a degree of polymerization.

4. The organic semiconductor film according to claim 1, wherein the organic-conductive high polymer compound is polythiophene represented by the following formula (I): 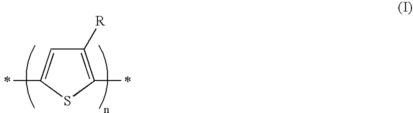
where in the formula (I) R is at least one selected from the group consisting of a hydrogen atom, a substituted or a not-substituted alkyl group and a substituted or a not-substituted carbocyclic ring, wherein the alkyl group is a straight or a branched alkyl group with a carbon number of 1 to 12 and n denotes a degree of polymerization.

5. The organic semiconductor film according to claim 1, wherein the organic conductive high polymer compound is polythiophene represented by the following formula (I): 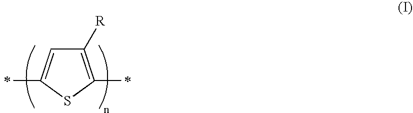
wherein the formula (I) R is at least one selected from the group consisting of a hydrogen atom, a substituted or a not-substituted alkyl group and a substituted or a not-substituted carbocyclic ring, wherein the carbocyclic ring is a saturated or an unsaturated carbocyclic ring with 3-20 ring carbon atoms, and is a monocyclic or a condensed ring and n denotes a degree of polymerization.

6. The organic semiconductor film according to claim 1, wherein the organic conductive high polymer compound is polythiophene represented by the following formula (I): 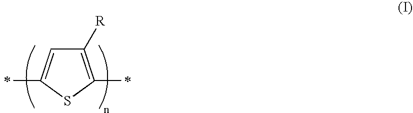
wherein the formula (I) R is at least one selected from the group consisting of a hydrogen atom, a substituted or a not-substituted alkyl group and a substituted or a not-substituted carbocyclic ring, wherein the substituent on the alkyl group or on the carbocyclic ring is at least one selected from the group consisting of halogen, a hydroxy group, a mercapto group, a carboxy group and a sulfo group and n denotes a degree of polymerization.

7. The organic semiconductor film according to claim 1, wherein the organic conductive high polymer compound is polythiophene represented by the following formula (I): 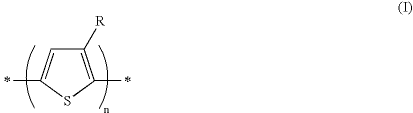
where in the formula (I) R is a n-hexyl group and n denotes a degree of polymerization.

8. The organic semiconductor film according to claim 1, wherein the organic conductive high polymer compound is polythiophene represented by the following formula (I): 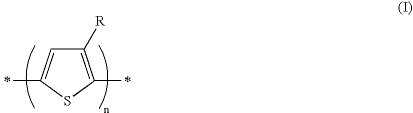
where in the formula (I) R is a hydrogen atom or an arbitrary substituent and n is an integer from 50 to 1,200.

9. The organic semiconductor film according to claim 1, wherein a molecular weight distribution range Mw/Mn ranges from 1.00 to 1.85, the Mw/Mn obtained by dividing a weight-average molecular weight Mw of the organic conductive high polymer compound by a number-average molecular weight Mn thereof.

10. The organic semiconductor film according to claim 1, wherein a weight-average molecular weight Mw of the organic conductive high polymer compound ranges from 41,000 to 55,000, and a number-average molecular weight Mn is 27,150 or more.

11. The organic semiconductor film according to claim 1, wherein, out of the two or more spectral peaks, an intensity of a peak on the shortest wavelength side is larger than or equal to intensities of any other peaks.

12. The organic semiconductor film according to claim 1, wherein, out of the two or more spectral peaks, a peak on the longest wavelength side exists in a wavelength region of 550 to 800 nm.

13. The organic semiconductor film according to claim 1, wherein, out of the two or more spectral peaks, a peak on the shortest wavelength side exists in a wavelength region of 350 to 575 nm, and at least one of the other peaks has a wavelength longer by 50 nm or more than a wavelength of the peak on the shortest wavelength side.

14. The organic semiconductor film according to claim 1, wherein carrier mobility of the organic semiconductor film is 10⁻⁴ cm²/V·s or more.

15. The organic semiconductor film according to claim 1, wherein carrier mobility of the organic semiconductor film is 10⁻² cm²/V·s or more.

16. The organic semiconductor film according to claim 1, wherein when in an X-ray diffraction (XRD) spectral diagram, two points at intersections of a peak-existing portion and a non-existing portion are connected by a straight line and when a relative intensity of diffraction X-ray at a vertex of the peak is i and a relative intensity of diffraction X-ray at a point on the straight line where a scattering angle 2θ is equal to the peak vertex is i₀, i/i₀ is 1.6 or more.

17. The organic semiconductor film according to claim 1, wherein when in an X-ray diffraction (XRD) spectral diagram, two points at intersections of a peak-existing portion and a non-existing portion are connected by a straight line and when a relative intensity of diffraction X-ray at a vertex of the peak is i and a relative intensity of diffraction X-ray at a point on the straight line where a scattering angle 2θ is equal to the peak vertex is i₀, i/i₀ is 1.8 or more.

18. An electron device comprising the organic semiconductor film according to claim 1 comprising an organic conductive high polymer compound, wherein the film shows two or more spectral peaks in a wavelength region of 300 to 800 nm by measurement of a visible and ultraviolet absorption spectrum method in a solid state.

19. The electron device according to claim 18, wherein the organic semiconductor film is formed on an insulation layer, and a face of the insulation layer at which the insulation layer contacts with the organic semiconductor film has a contact angle with respect to water of 13° or less.

20. The electron device according to claim 18, in the form of a thin film transistor (TFT).

21. A method for manufacturing an organic semiconductor film, comprising the steps of:
forming a solution in a thin film form, the solution comprising an organic conductive high polymer compound and showing two or more spectral peaks in a wavelength region of 300 to 800 nm by measurement using a visible and ultraviolet absorption spectral method; and
drying the solution formed in the thin film form.

22. The manufacturing method according to claim 21, wherein the organic conductive high polymer compound is polythiophene represented by the following formula (I): 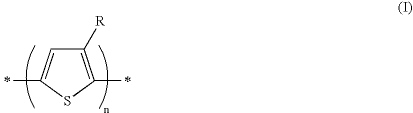
where in the formula (I) R is a hydrogen atom or an arbitrary substituent, and n denotes a degree of polymerization.

23. The manufacturing method according to claim 21, wherein, out of the two or more spectral peaks, an intensity of a peak on the shortest wavelength side is larger than or equal to intensities of any other peaks.

24. The manufacturing method according to claim 21, wherein, out of the two or more spectral peaks, a peak on the longest wavelength side exists in a wavelength region of 550 to 800 nm.

25. The manufacturing method according to claim 21, wherein, out of the two or more spectral peaks, a peak on the shortest wavelength side exists in a wavelength region of 300 to 500 nm, and at least one of the other peaks has a wavelength longer by 100 nm or more than a wavelength of the peak on the shortest wavelength side.

26. A method for manufacturing an organic semiconductor film, comprising the steps of:
forming a solution comprising an organic conductive high polymer compound in a thin film form; and
drying the solution formed in the thin film form,
wherein the organic conductive high polymer compound has a molecular weight distribution range Mw/Mn from 1.00 to 1.85, the Mw/Mn obtained by dividing a weight-average molecular weight Mw by a number-average molecular weight Mn.

27. The manufacturing method according to claim 26, wherein the organic conductive high polymer compound is polythiophene represented by the following formula (I): 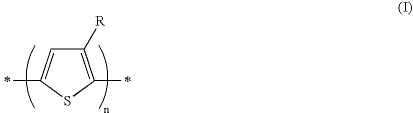
where in the formula (I) R is a hydrogen atom or an arbitrary substituent, and n denotes a degree of polymerization.

28. The manufacturing method according to claim 26, wherein the weight-average molecular weight Mw of the organic conductive high polymer compound ranges from 41,000 to 55,000, and the number-average molecular weight Mn is 27,150 or more.

29. The manufacturing method according to claim 21, wherein the organic conductive high polymer compound is polythiophene represented by the following formula (I): 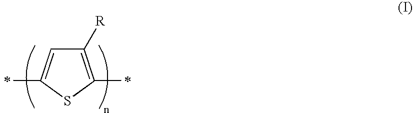
where in the formula (I) R is at least one selected from the group consisting of a hydrogen atom, a substituted or a not-substituted alkyl group and a substituted or a not-substituted carbocyclic ring group and n denotes a degree of polymerization.

30. The manufacturing method according to claim 21, wherein the organic conductive high polymer compound is polythiophene represented by the following formula (I): 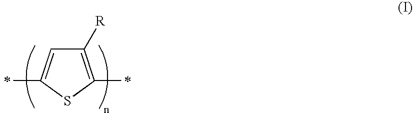
where in the formula (I) R is at least one selected from the group consisting of a hydrogen atom, a substituted or a not-substituted alkyl group and a substituted or a not-substituted carbocyclic ring, wherein the alkyl group is a straight or a branched alkyl group with a carbon number of 1 to 12 and n denotes a degree of polymerization.

31. The manufacturing method according to claim 21, wherein the organic conductive high polymer compound is polythiophene represented by the following formula (I): 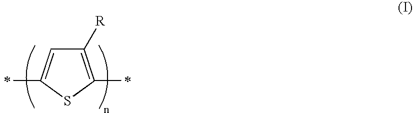
where in the formula (I) R is at least one selected from the group consisting of a hydrogen atom, a substituted or a not-substituted alkyl group and a substituted or a not-substituted carbocyclic ring, wherein the carbocyclic ring is a saturated or an unsaturated carbocyclic ring with 3-20 ring carbon atoms, and is a monocyclic or a condensed ring and n denotes a degree of polymerization.

32. The manufacturing method according to claim 21, wherein the organic conductive high polymer compound is polythiophene represented by the following formula (I): 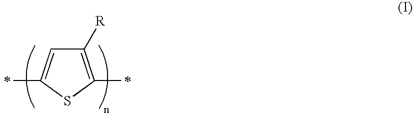
where in the formula (I) R is at least one selected from the group consisting of a hydrogen atom, a substituted or a not-substituted alkyl group and a substituted or a not-substituted carbocyclic ring, wherein the substituent on the alkyl group or on the carbocyclic ring is at least one selected from the group consisting of halogen, a hydroxy group, a mercapto group, a carboxy group and a sulfo group and n denotes a degree of polymerization.

33. The manufacturing method according to claim 22 21, wherein the organic conductive high polymer compound is polythiophene represented by the following formula (I): 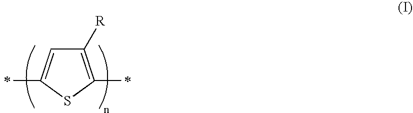
where in the formula (I) R is a n-hexyl group and n denotes a degree of polymerization.

34. The manufacturing method according to claim 21, wherein the organic conductive high polymer compound is polythiophene represented by the following formula (I): 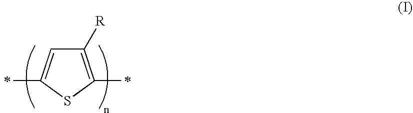
where in the formula (I) R is a hydrogen atom or an arbitrary substituent and n is an integer from 50 to 1,200.

35. The manufacturing method according to claim 21, wherein the organic conductive high polymer compound solution is allowed to stand still prior to the formation into a thin film form.

36. The manufacturing method according to claim 21, wherein the organic conductive high polymer compound solution is allowed to stand still prior to the formation into a thin film form, and the organic conductive high polymer compound solution is allowed to stand still until the solution becomes gel prior to the formation into a thin film form.

37. The manufacturing method according to claim 21, wherein the organic conductive high polymer compound solution is allowed to stand still prior the formation into a thin film form, and a time for allowing the organic conductive high polymer compound solution to stand still is 10 minutes or longer.

38. The manufacturing method according to claim 21, wherein a solvent of the organic conductive high polymer compound solution comprises at least one of aromatic hydrocarbon, halogenated aromatic hydrocarbon, aliphatic hydrocarbon and halogenated aliphatic hydrocarbon.

39. The manufacturing method according to claim 21, wherein a solvent of the organic conductive high polymer compound solution comprises at least one of benzene, toluene, o-xylene, m-xylene, p-xylene, chlorobenzene, o-dichlorobenzene, m-dichlorobenzene, p-dichlorobenzene, methylene chloride, chloroform, carbon tetrachloride and tetrachloroethylene.

40. The manufacturing method according to claim 21, further comprising the steps of:
preparing an insulator; and
conducting a plasma etching treatment on a surface of the insulator,
wherein the solution comprising the organic conductive high polymer compound is formed in a thin film form on the surface subjected to the plasma etching treatment.

41. The manufacturing method according to claim 21, further comprising the steps of:
preparing an insulator; and
conducting a plasma etching treatment on a surface of the insulator,
wherein the solution comprising the organic conductive high polymer compound is formed in a thin film form on the surface subjected to the plasma etching treatment, and the plasma etching treatment is conducted in an atmosphere containing oxygen gas.

42. A method for manufacturing an electron device comprising an organic semiconductor film, wherein the organic semiconductor film is manufactured by the manufacturing method according to claim 21.

43. A method for manufacturing an electron device comprising an organic semiconductor film, wherein the organic semiconductor film is manufactured by the manufacturing method according to claim 21, and the electron device is a thin film transistor (TFT).
